(19) United States
(12) Patent Application Publication
(10) Pub. No.: US 2006/0227603 A1
(43) Pub. Date: Oct. 12, 2006

(54) Recording method using link recording information

(75) Inventor: Sang-woo Park, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., LTD., Suwon-si (KR)

(21) Appl. No.: 11/349,245

(22) Filed: Feb. 8, 2006

(30) Foreign Application Priority Data
Mar. 8, 2005 (KR) 2005-19132

(51) Int. Cl. G11C 16/04; G11C 11/34

(52) U.S. Cl. 365/185.04

(57) ABSTRACT

A recording method using link recording information is provided to record the link program information on different kinds of recording media and read and regenerate the link information during the regenerating process so that a user may automatically link and watch the recorded information.

### CROSS-REFERENCE TO RELATED APPLICATIONS

This application claims all benefits accruing under 35 U.S.C. §119 from Korean Patent Application No. 2005-19132, filed Mar. 8, 2005, in the Korean Intellectual Property Office, the disclosure of which is incorporated by reference herein.

### BACKGROUND OF THE INVENTION

1. Field of the Invention

The present invention relates to a recording method, and more particularly to a recording method using link recording information recorded in different kinds of media.

2. Related Art

Recently, a variety of image multi-functional machines having multiple image devices using different kinds of recording media have been developed and commercialized in the market place. For example, image multi-functional machines incorporating video cassette recorder (VCR) capable of recording and regenerating analog video and audio signals on/from a recording medium such as a tape, or digital video recorder (DVR) capable of recording and regenerating digital video and audio data on/from a recording medium such as an optical disk, have been widely used by consumers.

In order to effectively utilize the recording and regenerating operation of a recording medium such as a tape or a disk, link recording information may be utilized to link the recording on different kinds of recording media, as disclosed in Korean Laid-open Publication No. 10-2004-0075238, entitled as “Link Recording and Regenerating Method of An Image Multi-function Machine.” Specifically, in the Korean Laid-open Publication No. 10-2004-0075238, a technique for making link recording in different kinds of recording media during a recording operation and generating link recording information for link regeneration of each recording medium corresponding to the link recording to be recorded therein is disclosed. As a result, the program link-recorded on each recording medium may be regenerated in series with reference to the link recording information while regeneration operation can be conducted at a later time.

FIG. 1 illustrates an example image multi-functional machine utilizing different kinds of recording media, such as a tape and a disk. As shown in FIG. 1, the image multi-functional machine comprises a tape deck 10 arranged to accommodate a tape (not shown) as a recording medium; a tape record/play system 11 arranged to record/play back information (analog video and/or audio signals) recorded on a tape; a switching unit 12; a disk deck 13 arranged to accommodate an optical disk (not shown) as a recording medium; a disk record/play system 14 arranged to record/play back information (digital video and/or audio signals) recorded on the disk; a micro-computer 15 configured to control the operation of the multi-functional machine, including, for example, the tape record/play system 11, the disk record/play system 14, and the switching unit 12 for switching between the tape record/play system 11 and the disk record/play system 14; a memory 16 arranged to store link recording information; and an on-screen display (OSD) generator 17 arranged to provide on-screen display of messages for a user.

FIG. 2 and FIG. 3 show flowcharts of a link recording method and a link regenerating method by reservation of the image multi-functional machine, shown in FIG. 1.

As shown in FIG. 2, when a recording mode is set by a user, via a key input device (not shown) at block S10, a micro-computer 15 selects a recording medium used for recording, i.e., whether a tape is inserted into a tape deck 10 or a disk is inserted into a disk deck 13 at block S11.

For example, in case the disk is selected for a recording operation, the micro-computer 15 controls the switching unit 12 to switch over to the disk record/play system 14, and controls the disk record/play system 14 to conduct a series of recording operations for recording digital video and audio signals input from an external source onto the disk serving as a recording medium at block S12. Alternatively, if the tape is selected for a recording operation, then the micro-computer 15 controls the switching unit 12 to switch over to the tape record/play system 14, and controls the tape record/play system 11 to conduct a series of recording operations for recording analog video and audio signals input from an external source onto the tape serving as a recording medium.

After that, while the recording operation is conducted for the recording medium (i.e., a tape or a disk) the micro-computer 15 determines if the recording has ended at block S13. If the recording has not ended, the micro-computer 15 determines if the recording medium is ended at block S14, for example, if a recording capacity of the recording medium is full, and is not able to record any additional data, the micro-computer 15 checks whether any link recording is preset by a user at block S15, or controls the OSD generator 17 to provide a visual display of an OSD image inquiring whether or not to conduct the link recording.

In addition, in case a user sets link recording through the OSD image at block S15, the micro-computer 15 generates link recording information and then stores the link recording information in a memory 16 at block S16. At this time, the link recording information includes a number of programs or play lists for recognizing a program recorded on the recording medium, recording start media identification information (Rec_Start_Media), and a recording start time (Rec_Start_Time) and a recording end time (Rec_End_Time) of the corresponding program.

Meanwhile, the micro-computer 15 records the link recording information as described into the memory 16. If a disk is selected as a recording medium at block S11, the micro-computer 15 then controls the switching unit 12 and the tape record/play system 11 to conduct a series of link recording operation so that video and audio signals input from an external source are D/A converted and then the D/A converted analog video and audio signals are link-recorded onto the tape serving as a recording medium at block S17.

After that, the micro-computer 15 determines if the recording operation has completed at block S18. If the recording operation has ended, the micro-computer 15 updates the link recording information stored in the memory 16 at block S19. At this time, the link recording information to be updated includes corresponding recording link recording media (Rec_Llink_Media), and recording start time (Rec_Start_Time) and recording end time (Rec_End_Time) of the program link-recorded on the tape serving as a recording medium.

As a result, a single program can be link-recorded on the disk recording medium and the tape recording medium respectively, and the corresponding link recording information can be stored and managed in the memory 16.

As shown in FIG. 3, when a regeneration mode is set by a user, via a key input device (not show) at block S30, the micro-computer 15 selects a regeneration recording medium, that is, a recording medium selected between the tape inserted into the tape deck 10 and the disk inserted into the disk deck 13 used for the regeneration operation at block S31.

After that, while the regeneration operation is conducted for the recording medium (i.e., a tape or a disk), the micro-computer 15 determines if the regeneration has ended at block S33. If the regeneration has not ended, the micro-computer 15 determines if the recording medium is ended at block S34, that is, for example, if data recorded on the disk recording medium is all regenerated and is not able to regenerate data any more. If the recording medium is ended, the micro-computer 15 checks whether any link regeneration is preset by a user at block S35, or controls the OSD generator 17 to provide a visual display of an OSD image inquiring whether or not to make a link regeneration.

In addition, in case a user sets link regeneration through the OSD image at block S35, the micro-computer 15 extracts and checks the link recording information previously stored in the memory 16 at block S36. At this time, the link recording information includes a number of programs or play lists for identifying program recorded on the disk serving as a recording medium, recording start recording media identification information, and recording start and end time of the corresponding program. In addition, recording link recording media identification (ID) information corresponding to the tape serving as a recording medium, and recording start and end time of the program recorded in the tape serving as a recording medium are included therein.

Meanwhile, the micro-computer 15 reads and refers to the link recording information as described from the memory 16. If a tape is selected as a regeneration recording medium at block S31, the micro-computer 15 then controls the switching unit 12 and the tape record/play system 11 to conduct a series of link regeneration operations so that remaining portions of the corresponding program recorded on the tape recording medium is regenerated at block S37.

After that, the micro-computer 15 determines if the regeneration has ended at block S38, that is, if the user has submitted a request to end the regeneration operation, or a regeneration position corresponding to the recording end time of the tape recording medium included in the link recording information is detected. If the regeneration has ended, the micro-computer 15 simply ends the link regeneration operation.

As a result, the program link-recorded on the disk recording medium and the tape recording medium may be regenerated continuously for a long time, so that a user can efficiently enjoy the link-recorded program recorded on the disk recording medium and the tape recording medium respectively.

However, such a link recording and regenerating device uses identification (ID) number of link program and relevant information recorded in the memory. As a result, data recorded on one recording medium may not be regenerated from another recording medium. That is to say, since data is limited to the corresponding set, there is no compatibility between different recording media.

In addition, since the memory must be used to store link recording information, the price of the entire machine is increased and productivity is deteriorated.

### SUMMARY OF THE INVENTION

Various aspects and example embodiments of the present invention advantageously provide cost-effective techniques for enabling link recording information to be recorded and used in an image multi-function machine, and for enabling recording, regenerating and erasing information on/from different kinds of recording media, while providing compatibility between different recording media and eliminating the use of an internal memory.

Additional aspects and/or advantages of the invention will be set forth in part in the description which follows and, in part, will be obvious from the description, or may be learned by practice of the invention.

In accordance with an aspect of the present invention, a link recording method of an image multi-function machine having different kinds of recording media is provided with generating link recording information for conducting link regeneration when the link recording operation is made; and recording the link recording information on the recording media.

Preferably, the information recording information is recorded on a recording medium that conducts the recording operation in advance of the link regeneration, and the link recording information includes a recording start position, a recording end position and a bookmark number of the corresponding recording medium, and a bookmark number of another recording medium. In addition, the bookmark numbers are preferably recorded on each medium with different serial codes.

The link recording information generation may include determining whether a recording capacity of a recording medium has exceeded while the recording operation is conducted to the corresponding recording medium; checking whether a link recording mode is set when the recording capacity has exceeded; and generating link recording information to be recorded on the recording medium when the link recording mode is set.

The information recording information may include searching a recording area of a recording medium used for the link recording; and recording the link recording information of the area, searched in the searching step, on the recording medium.

The searching of a recording area on the recording medium may also include firstly searching a recording area of the recording medium used for the link recording; secondly searching whether the recording area searched is capable of recording a remaining time of a corresponding recording program; thirdly searching whether a forcible erasing mode is set when the searched recording area is insufficient for the remaining time; and setting the program to be forcibly erased as an area for link recording when the forcible erasing mode is set.

In accordance with another aspect of the present invention, there is also provided a link recording information generating method of an image multi-function machine having a link recording function capable of link-recording data on different kinds of recording media. Such a link recording information generating method comprises generating bookmark information for a recording medium that is used former; generating another bookmark information for a recording medium that is used later; and generating the bookmark information for the former recording medium and the bookmark information for the later recording medium as link recording information.

Meanwhile, the link recording information preferably includes a recording start position and a recording end position of each recording medium for the user's convenience.

In accordance with still another aspect of the present invention, there is also provided a link recording information erasing method of different kinds of recording media in which program and link recording information are recorded. Such a link recording information erasing method comprises selecting a program to be erased; determining whether the program to be erased includes link recording information; erasing the corresponding program and link program stored on another recording medium when the program is a program of a former recording medium including the link recording information; and selecting whether to delete the link program of the recording medium when the program to be erased is a program of a later recording medium including the link recording information.

In accordance with yet another aspect of the present invention, there is also provided a link regenerating method of an image multi-function machine having different kinds of recording media incorporated therein, on which program and link recording information are recorded. Such a link regenerating method comprises selecting and regenerating a program recorded on any recording medium; reading a link program of another recording medium recorded in the selected and regenerated program; and regenerating the link program read.

The link program regenerating step preferably includes searching the link program and standing by; and continuously regenerating the link program when the program is completely regenerated.

Also preferably, the link recording information includes a recording start position, a recording end position and a bookmark number of the corresponding recording medium, and a bookmark number of another recording medium, and the bookmark numbers are recorded on each recording medium with different serial codes.

In addition to the example embodiments and aspects as described above, further aspects and embodiments of the present invention will be apparent by reference to the drawings and by study of the following descriptions.

### BRIEF DESCRIPTION OF THE DRAWINGS

A better understanding of the present invention will become apparent from the following detailed description of example embodiments and the claims when read in connection with the accompanying drawings, all forming a part of the disclosure of this invention. While the following written and illustrated disclosure focuses on disclosing example embodiments of the invention, it should be clearly understood that the same is by way of illustration and example only and that the invention is not limited thereto. The spirit and scope of the present invention are limited only by the terms of the appended claims. The following represents brief descriptions of the drawings, wherein:

FIG. 1 illustrates an example image multi-function machine;

FIG. 2 is a flowchart of a link recording method of the image multi-function machine shown in FIG. 1;

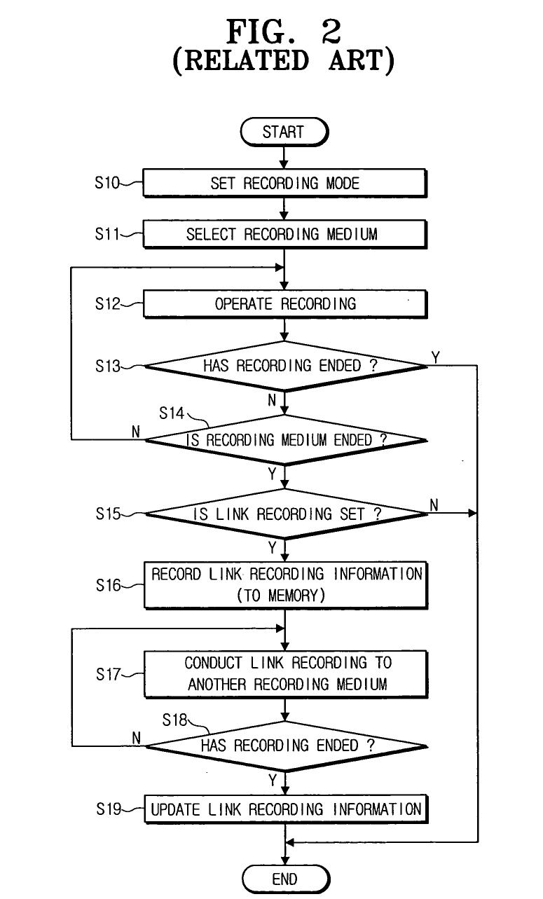

FIG. 3 is a flowchart of a link regenerating method of the image multi-function machine shown in FIG. 1;

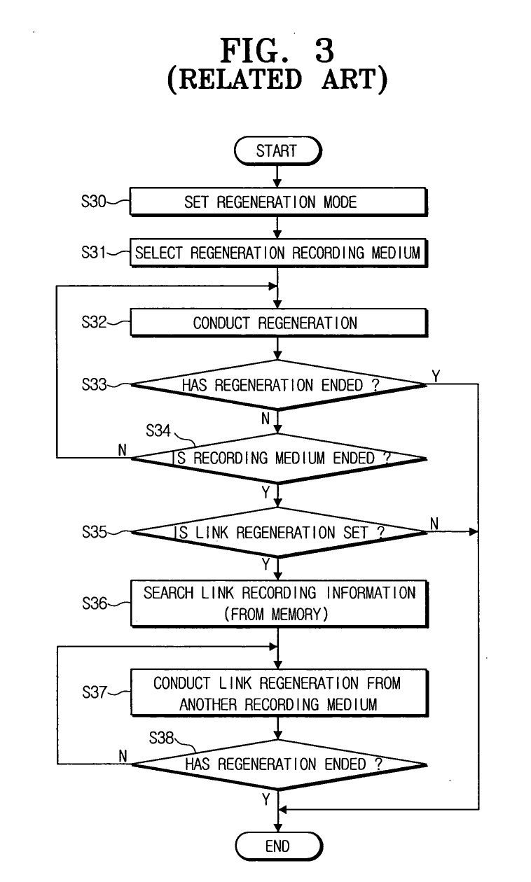

FIG. 4 is a schematic view of a link recording method according to an embodiment of the present invention;

FIG. 5 is a flowchart of a reservation recording setting process according to an embodiment of the present invention;

FIG. 6 is a flowchart of an example recording process of different kinds of recording media according to an embodiment of the present invention; and

FIG. 7 is a flowchart of an example regenerating process according to an embodiment of the present invention.

### DETAILED DESCRIPTION OF THE PREFERRED EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

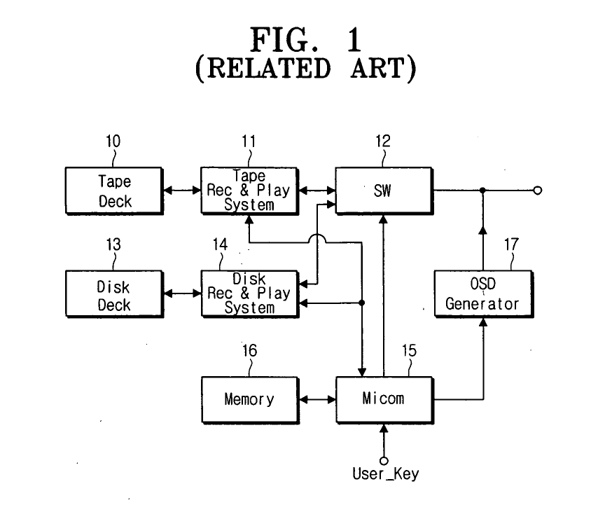

The present invention will be described using the components of an example image multi-functional machine shown in FIG. 1, where first and second recording media, such as a tape and a disk, are capable of recording reservation information and bookmark information. However, a memory 16 is no longer required. In addition, a tape record/play system 11 and a disk record/play system 14, as shown in FIG. 1, can be integrated into a single component, or into the micro-computer 15. As a result, a switching unit 12 may not be required.

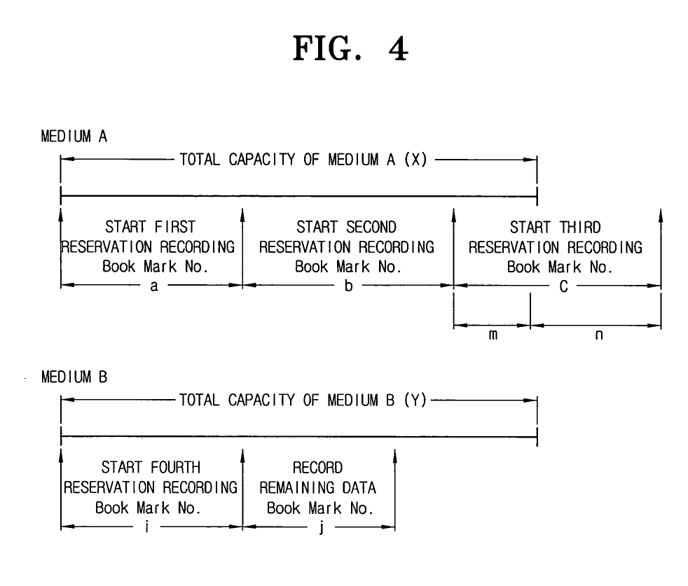

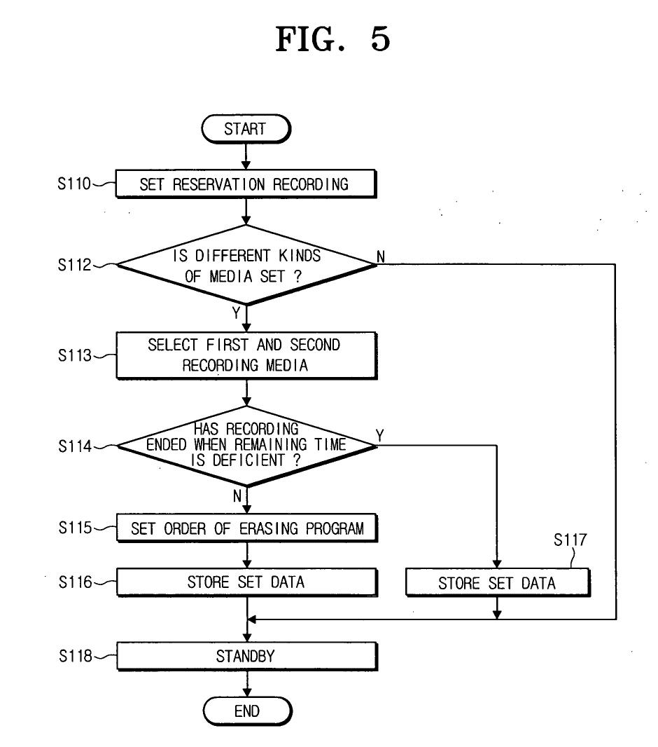

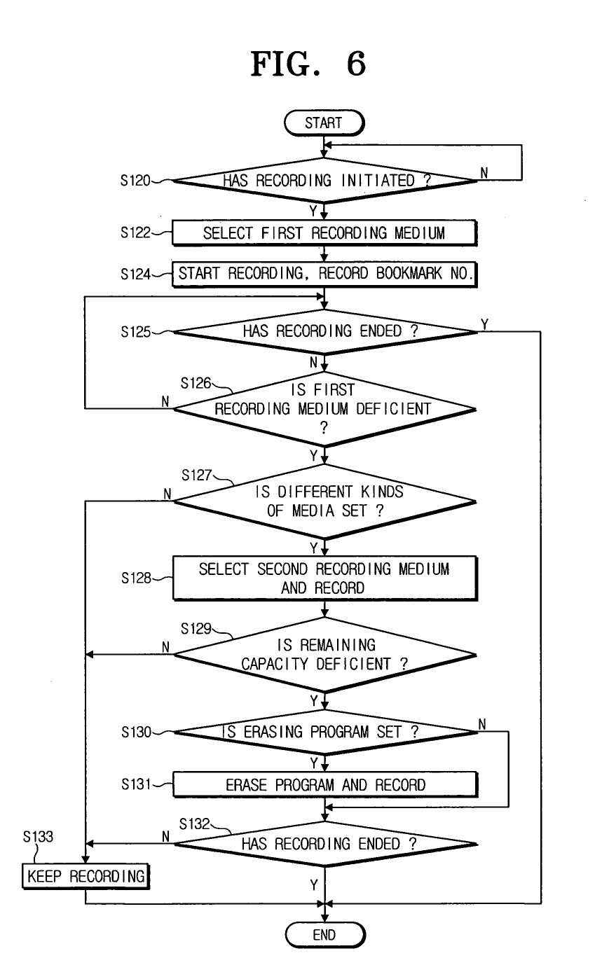

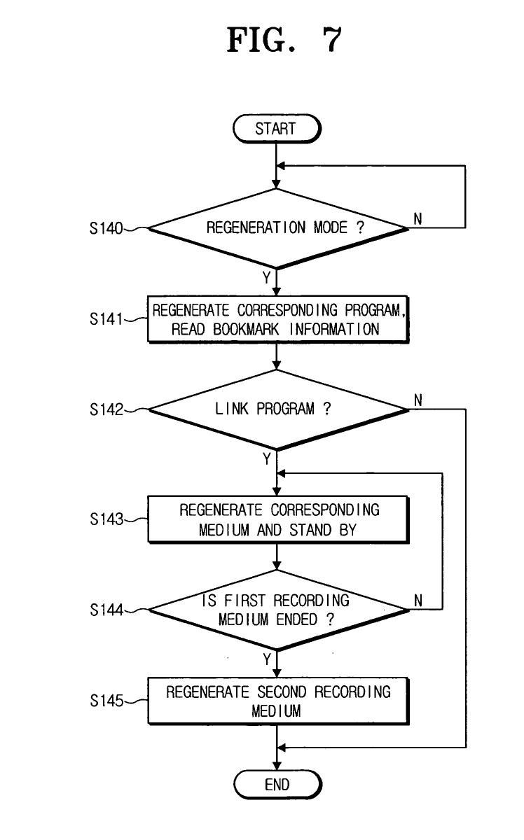

Specifically, FIG. 4 is a schematic view illustrating a link recording method according to an embodiment of the present invention; FIG. 5 is a flowchart illustrating a reservation recording setting process according to an embodiment of the present invention; FIG. 6 is a flowchart illustrating a recording process of different kinds of recording media according to an embodiment of the present invention; and FIG. 7 is a flowchart illustrating a regenerating process according to an embodiment of the present invention.

Referring to FIG. 4, a recording medium “A” can be an optical disk such as a digital versatile disk (DVD) and a recording medium “B” can be a video tape. However, the present invention is not limited thereto. The optical disk can be any member of a DVD family, including DVD-R, DVD−RW, DVD+RW, DVD-RAM, DVD-ROM, or a CD family, including, CD-R, CD-RW, and CD-ROM. Moreover, such an optical disk can also be any high-density medium, such as a blue-ray disc (BD) and an advanced optical disc (AOD). Likewise, the videotape can also be other types of magnetic media. In addition, the image multi-functional machine shown in FIG. 1, can be a single device or multiple devices incorporated therein, such as a video cassette recorder “VCR”, a digital video recorder “DVR”.

First, a micro-computer 15 operates a disk deck 13 so that a first reservation recording content having bookmark No. “a” and a second reservation recording content having bookmark No. “b” are already recorded on the medium A.

In addition, the micro-computer 15 operates a tape deck 10 so that a fourth reservation content having bookmark No. “i” is recorded on the medium B.

At this time, a disk record/play system 14 operates so that information related to reservation recording, such as a start position and an end position, is recorded in an information region (hereinafter, refer to as “information display region”) of a DVD system together with the bookmark information. Similarly, a tape record/play system 11 also operates so that information related to reservation recording, such as a start position and an end position, is recorded in a separate information display region together with the bookmark information.

In particular, in case of a videotape, information may be read from the information display region using a VISS (Video Index Search System), a VASS (Video Address Search System) or a caption function.

Meanwhile, the bookmark No. recorded on the DVD and the video tape is preferably configured with serial codes so that the DVD and the video tape may be distinguishable from each other. For example, bookmark numbers for the medium A can be recorded in an order of, for example, “a, b, c”. Similarly, bookmark numbers for the medium B can be recorded in an order of, for example, “i, j, k”. This way they may be distinguishable from each other.

In addition, the micro-computer 15 reads a program recorded on the media A and B and always possesses a remaining recording time (Remain Time). And then, if a reservation recording time set by a user who selects a predetermined medium exceeds the remaining recording time of the corresponding medium, another medium can preferably be linked for the reservation recording.

That is to say, in case that it is set that the reservation-recorded contents of the medium A selected by a user may be recorded in link with the medium B, such as the third reservation recording content having bookmark No. (c), as shown in FIG. 4, the micro-computer 15 controls the disk record/play system 14 and the tape record/play system 11 to record the contents on the medium A for a predetermined time and then continuously record remaining contents in an empty area of the medium B for a remaining time (n).

At this time, in case the link recording is conducted as described (see the third reservation recording content having bookmark No. (c) as shown in FIG. 4), when the bookmark No. (c) is recorded on the medium A, the micro-computer 15 makes the bookmark No. (j) be link-recorded on the corresponding medium B for automatic linkage thereof.

That is to say, it may be easily determined whether link recording is set when referring to the reservation recording start/end position of the information display region, corresponding bookmark No. and the bookmark No. of the medium B.

The link recording information for such link recording may be set in various ways by adding information and identifiers related to the link recording.

Hereinafter, the process of setting reservation recording according to an embodiment of the present invention is described with reference to FIG. 5. First, if a user sets the reservation recording setting mode, via a key input device (not shown) such as a remote controller at block S110, the micro-computer 15 allows the user to set reservation recording for different kinds of recording media at block S112.

In a product configured with different kinds of recording media as disclosed in the present invention, a user is generally provided with the ability to select a medium for recording a corresponding program when the reservation recording is set. A selection screen for the above action can be easily provided and configured using GUI (Graphic User Interface).

If the reservation recording for different kinds of recording media is set so as to allow user selection in block S112, a user can select between a first recording medium and a second recording medium at block S113. As previously discussed, the first recording medium can be a DVD, and the second recording medium can be a video tape.

In addition, in case that recording for the first recording medium is initiated, it is preferable to allow a user to select whether the recording operation should be forcibly stopped when a remaining time is deficient in preparation of deficient remaining time, or the data should be recorded in duplicate with the already recorded contents, when the contents reservation-recorded in the second recording medium is recorded. Specifically, the micro-computer 15 determines if the recording operation has ended when a remaining time is deficient at block S114.

In case that the duplicate recording is selected at block S114, the user is allowed to select an order of programs to be erased at block S115.

The reservation-recorded contents set as described is then recorded in the memory 16 at block S116 and block S117, and then the system is changed into a stand-by mode and searches a reservation recording time, thereby completing the reservation recording procedure at block S118.

A process of recording the reservation-recorded contents on different kinds of recording media as discussed above will now be described in detail with reference to FIG. 6 as follows.

First, the micro-computer 15 compares a reservation recording time with a current time, and determines whether or not to initiate recording at block S120. If the recording time comes, the micro-computer 15 reads information set during the reservation recording to receive relative program for recording, and selects a first recording medium for recording at block S122.

If a first recording medium used for recording is selected at block S122, the corresponding record/play system (i.e., a tape record/play system 11 or a disk record/play system 14, as shown in FIG. 1) is operated to initiate recording. In addition, a bookmark No. and a recording start position are recorded in the information display region at block S124.

The micro-computer 15 then determines if the recording has ended at block S125, that is, if a recording end time comes during the recording. If the recording end time comes during the recording, a recording end position is recorded in the information display region and the recording mode is ended.

While the recording is progressed, the micro-computer 15 checks whether a remaining capacity of the first recording medium currently used for recording is deficient at block S126.

If the recording remaining capacity of the first recording medium is deficient at block S126, the micro-computer 15 checks whether a different kind of medium is set during the reservation recording setting at block S127.

If different kinds of recording media are not set, recording is continued until ended at block S133. The recording can be ended when the first recording medium no long has any remaining capacity used for recording. If different kinds of recording media are set, the system is controlled so that a second recording medium is linked for recording at block S128. Of course, the first recording medium displays a recording end region on the information display region, and also records the link bookmark No. as described above.

Preferably, the corresponding record/play system (i.e., a tape record/play system 11 or a disk record/play system 14, as shown in FIG. 1) of the second recording medium used for link recording is operated to stand by for instant recording.

In case that the link program is recorded in the second recording medium, it is further preferred that an empty area of the second recording medium is arbitrarily selected for recording. If a remaining capacity of the second recording medium is deficient during recording of the second recording medium at block S129, the micro-computer 15 determines if an erasing program is set at block S130. If there is set an erasing program, the corresponding program is selected for erasing and the corresponding program is continuously recorded at block S131.

At this time, the link bookmark No. is also recorded on the information display region so that linking and regeneration may be ensured.

After that, the micro-computer 15 determines whether the recording has ended at block S132.

Now, a process of regenerating a program recorded as discussed above is described with reference to FIG. 7.

If a current mode is a regeneration mode at block S140, the micro-computer 15 selects any recording medium used for regeneration, and then controls the corresponding record/play system (i.e., a tape record/play system 11 or a disk record/play system 14, as shown in FIG. 1) to generate the corresponding program and reads the bookmark No. recorded in the corresponding information display region at block S141.

If information for the link program (e.g., bookmark No.) is recorded in the information display region at block S142, the micro-computer 15 operates the corresponding record/play system (i.e., a tape record/play system 11 or a disk record/play system 14, as shown in FIG. 1) to maintain in a standby state so that the corresponding link program may be generated at block S143.

During a standby state, if the generation of the first recording medium has ended at block S144, a second recording medium on which the corresponding link program is recorded can be continuously regenerated at block S145.

As mentioned above, since the information of the link program is displayed on the corresponding recording medium without using a separate memory, the link program may be easily recorded thereon and regenerated therefrom.

In addition, in case that the program as recorded in the manner described by the present invention is link-recorded on the first and second recording media, if a user desires to delete the program of the first recording medium, the system is operated so that the link program recorded on the first and second recording media is all deleted. If the user desires to delete the link program recorded on the second recording medium, the system preferably outputs a message for checking whether the link program recorded in the first recording medium should also be deleted.

Also, though it has been described that the micro-computer 15, the tape record/play system 11 and the disk record/play system 14 for operating the first and second recording media are controlled through protocol, they may also be configured and integrated in a single controller or microcomputer.

According to the recording method using the link recording information of the present invention, a user may record data regardless of a remaining capacity of a recording medium and also may watch a recorded program automatically without searching the program.

In addition, since the link recording information may be displayed on the recording media, compatibility between different kinds of recording media may be kept, not limited to a specific set, and also productivity may be enhanced.

Although the preferred embodiment of the present invention has been described, it will be understood by those skilled in the art that the present invention should not be limited to the described preferred embodiment, but various changes and modifications can be made within the spirit and scope of the present invention. For example, components of an image multi-functional machine, as shown in FIG. 1, can be arranged differently, or integrated therein, as long as different kinds of recording media can be utilized in the manner as described. Similarly, the tape record/play system 11 and the disk record/play system 14 can be incorporated into existing components of the image multi-functional machine, such as a system controller. Moreover, such a system controller can be implemented as a chipset having firmware, or alternatively, a general or special purposed computer programmed to implement methods as described with reference to FIG. 5, FIG. 6 and FIG. 7. Accordingly, it is intended, therefore, that the present invention not be limited to the various example embodiments disclosed, but that the present invention includes all embodiments falling within the scope of the appended claims.

What is claimed is:

1. A link recording method of an image multi-function machine having different kinds of recording media incorporated therein, comprising:
generating link recording information for conducting link regeneration when a link recording operation is made; and
recording the link recording information on the recording media.

2. The link recording method according to claim 1, wherein the link recording information is recorded on a recording medium that conducts a recording operation in advance of the link regeneration.

3. The link recording method according to claim 2, wherein the link recording information includes a recording start position, a recording end position and a bookmark number of the corresponding recording medium, and a bookmark number of another recording medium.

4. The link recording method according to claim 3, wherein the bookmark numbers are recorded on each recording medium with different serial codes.

5. The link recording method according to claim 1, wherein the link recording information generation comprises:
determining whether a recording capacity of a recording medium has exceeded while the recording operation is conducted to the corresponding recording medium;
checking whether a link recording mode is set when the recording capacity has exceeded; and
generating link recording information to be recorded on the recording medium when the link recording mode is set.

6. The link recording method according to claim 1, wherein the link recording information recording comprises:
searching a recording area of a recording medium used for the link recording; and
recording the link recording information in the recording area on the recording medium.

7. The link recording method according to claim 6, wherein the searching of a recording area on the recording medium comprises:
searching a recording area of the recording medium used for the link recording;
searching whether the recording area searched is capable of recording a remaining time of a corresponding recording program;
searching whether a forcible erasing mode is set when the searched recording area is insufficient for the remaining time; and
setting the program to be forcibly erased as an area for link recording when the forcible erasing mode is set.

8. A link recording information generating method of an image multi-function machine having a link recording function capable of link-recording data on different kinds of recording media, comprising:
generating bookmark information for a recording medium that is used former;
generating another bookmark information for a recording medium that is used later; and
generating the bookmark information for the former recording medium and the bookmark information for the later recording medium as link recording information.

9. The link recording information generating method according to claim 8, wherein the link recording information includes a recording start position and a recording end position on each recording medium.

10. A link recording information erasing method of different kinds of recording media in which program and link recording information are recorded, comprising:
selecting a program to be erased;
determining whether the program to be erased includes link recording information; and
erasing the corresponding program and a link program stored on another recording medium when the program is a program of a former recording medium including the link recording information.

11. The link recording information erasing method according to claim 10, further comprising:
selecting whether to delete the link program of the recording medium when the program to be erased is a program of a later recording medium including the link recording information.

12. A link regenerating method of an image multi-function machine having different kinds of recording media incorporated therein, on which program and link recording information are recorded, the method comprising:
selecting and regenerating a program recorded on any recording medium;
reading a link program of another recording medium recorded in the selected and regenerated program; and
regenerating the link program read.

13. The link regenerating method according to claim 12, wherein the link program regenerating comprises:
regenerating a recording medium on which the link program is recorded,
searching the link program and standing by; and
continuously regenerating the link program when the program is completely regenerated.

14. The link regenerating method according to claim 12, wherein the link recording information includes a recording start position, a recording end position and a bookmark number of the corresponding recording medium, and a bookmark number of another recording medium.

15. The link regenerating method according to claim 14, wherein the bookmark numbers are recorded on each recording medium with different serial codes.

16. A multi-functional apparatus comprising:
a first deck arranged to receive a first recording medium;
a second deck arranged to receive a second recording medium different from the first recording medium;
a record/play system arranged to record/play back information recorded on the first recording medium or the second recording medium; and
a controller configured to control the operation of the first deck, the second deck and the record/play system, including to set reservation recording for the first and second recording media, to select recording information on one of the first and second recording media, and if a selected one of the first and second recording media is full during recording, to automatically select link recording a remaining portion of the information on a remaining one of the first and second recording media.

17. The multi-functional apparatus according to claim 16, wherein the controller is configured to respond to a user's request to set reservation recording for the first and second recording media, via an on-screen display.

18. The multi-functional apparatus according to claim 16, wherein the controller is configured to generate link recording information, when link recording is selected, and to record the link recording information on both the first and second recording media, the link recording information representing recording start/end positions and a bookmark number of the selected one of the first and second recording media and a bookmark number.

19. The multi-functional apparatus according to claim 18, wherein the bookmark numbers are recorded on the first and second recording media with different serial codes.

20. The multi-functional apparatus according to claim 18, wherein the controller is further configured to regenerate, during a regeneration mode, information recorded on the first and second recording media continuously, based on the link recording information.

21. The multi-functional apparatus according to claim 16, wherein the first recording medium corresponds to a video tape, and the second recording medium corresponds to a DVD.

22. The multi-functional apparatus according to claim 16, further comprising an on-screen display (OSD) generator arranged to provide on-screen display of messages for a user to set the reservation recording, and initiate the recording process and the regenerating process.
